(19) United States
(12) Patent Application Publication
(10) Pub. No.: US 2024/0332251 A1
(43) Pub. Date: Oct. 3, 2024

(54) DUMMY SILICON STIFFENING MECHANISM FOR MODULE WARPAGE MITIGATION

(71) Applicant: Intel Corporation, Santa Clara, CA (US)

(72) Inventors: Min Suet LIM, Gelugor (MY); Kavitha NAGARAJAN, Bangalore (IN); Stephan STOECKL, Schwandorf (DE); Eng Huat GOH, Ayer Itam (MY)

(21) Appl. No.: 18/129,878

(22) Filed: Apr. 2, 2023

(51) Int. Cl. H01L 25/065; H01L 23/00; H01L 23/498

(52) U.S. Cl. CPC H01L 25/0652; H01L 23/49816; H01L 24/16; H01L 24/32; H01L 2224/16225; H01L 2224/32225; H01L 2924/1432; H01L 2924/1433; H01L 2924/1436; H01L 2924/3511; H10B 80/00

(57) ABSTRACT

Embodiments disclosed herein include electronic packages. In an embodiment, the electronic package comprises a substrate with a first surface and a second surface opposite from the first surface. In an embodiment, a plurality of first dies are coupled to the first surface of the substrate, and a bump field is on the second surface of the substrate. In an embodiment, the bump field comprises a voided region towards a center of the substrate. In an embodiment, a second die is coupled to the second surface of the substrate, where the second die is provided in the voided region.

### TECHNICAL FIELD

Embodiments of the present disclosure relate to electronic systems, and more particularly to system in package (SIP) architectures that include dummy silicon structures in order to mitigate warpage.

### BACKGROUND

Warpage is a significant engineering challenge to overcome for larger package architectures. One such architecture includes system in package (SIP) architectures. In SIP systems, one or more compute dies are coupled to a substrate. In addition to compute dies, memory dies, power management integrated circuits (PMICs), and the like may also be provided over the substrate. The high volume of semiconductor material on a single side of the substrate leads to significant warpage, especially when the substrate has a low thickness. The warpage of the underlying substrate increases the difficulty with attaching the substrate to an underlying board, such as a printed circuit board. For example, the warpage may lead to solder bridging, open circuits, or other interconnect defects.

There are some solutions to warpage problems. However, existing solutions have negative drawbacks. For example, system footprints (in the X-Y plane) will be increased. Additionally, some existing solutions will lead to larger Z-heights. In the drive to smaller, more compact, architectures, such limitations can be show stoppers in the design of advanced SIP architectures.

### BRIEF DESCRIPTION OF THE DRAWINGS

FIG. 1A is a plan view illustration of the front side a system in package (SIP) that includes a compute die, memory dies, and power management integrated circuits (PMICs), in accordance with an embodiment.

FIG. 1B is a plan view illustration of the backside of a module that illustrates the bump field with a void at a center of the substrate, in accordance with an embodiment.

FIG. 2 is a cross-sectional illustration of a module that is mounted to a board that illustrates issues with excessive warpage, in accordance with an embodiment.

FIG. 3 is a plan view illustration of a module that includes a stiffener that increases the X-Y footprint of the module, in accordance with an embodiment.

FIG. 4 is a cross-sectional illustration of a module that is mounted to a board that illustrates a substrate with increased thickness in order to mitigate warpage, in accordance with an embodiment.

FIG. 5 is a cross-sectional illustration of a module that is mounted to a board with solder bumps that are larger in width and standoff height, which increases the form factor of the system, in accordance with an embodiment.

FIG. 6A is a cross-sectional illustration of a module that is mounted to a board with a dummy silicon die coupled to the board by an adhesive within the bump field void, in accordance with an embodiment.

FIG. 6B is a cross-sectional illustration of a module that is mounted to a board with a die coupled to the board by solder bumps within the bump field void, in accordance with an embodiment.

FIG. 7A is a cross-sectional illustration of a module that is mounted to a board with a dummy silicon die coupled to the module substrate by an adhesive within the bump field void, in accordance with an embodiment.

FIG. 7B is a cross-sectional illustration of a module that is mounted to a board with a die coupled to the module substrate by solder within the bump field void, in accordance with an embodiment.

FIG. 8 is a schematic of a computing device built in accordance with an embodiment.

### EMBODIMENTS OF THE PRESENT DISCLOSURE

Described herein are electronic systems, and more particularly to system in package (SIP) architectures that include dummy silicon structures in order to mitigate warpage, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, large scale packages suffer from significant warpage. The warpage may be attributable to several different factors. In one instance the large volume of silicon or other low coefficient of thermal expansion (CTE) material on a single side of an organic substrate (e.g., a board, a package substrate, etc.) may result in warpage due to the CTE mismatch. When a low CTE material, such as silicon, is provided over the top surface of a high CTE material, such as organic layers in a board, the structure will result in warpage that is bowl shaped. When the warpage is significant, the interconnects provided between the package substrate and an underlying board (e.g., a printed circuit board (PCB)) can include defects. Defects (e.g., solder bridging, non-contact opens, and the like) are common in the assembly of warped features. Accordingly, careful design of such large systems is needed in order to mitigate assembly issues attributable to warpage.

One such large scale package architecture is a system in package (SIP) architecture. In a SIP architecture, multiple different die types are provided on a single SIP substrate. For example, compute dies, memory dies, power management integrated circuits (PMICs), and the like may all be provided on a single surface (i.e., a top surface) of the SIP substrate. Such heavy loading of low CTE materials leads to significant warpage concerns. Some solutions have been proposed to mitigate the warpage, but they come with the disadvantages of increased assembly cost, increased form factor, and/or other negative attributes.

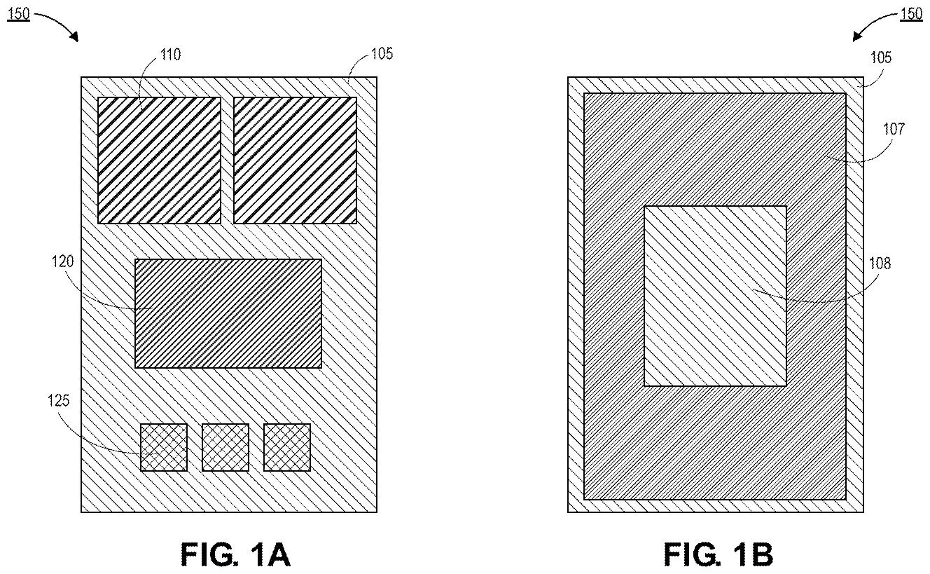

In order to provide context to embodiments described in greater detail below, FIG. 1A provides a plan view illustration of on exemplary module 150. As shown, the module 150 may include a substrate 105. The substrate 105 may be a board or a package substrate. Generally speaking, the substrate 105 may include organic layers (with or without fiber reinforcement) that are laminated over each other. The substrate 105 may also comprise a core in some embodiments. Since the substrate 105 is largely formed with organic materials, the CTE of the substrate 105 may be relatively high. For example, the CTE of silicon may be approximately 3 ppm/° C. and the CTE of the substrate 105 (e.g., a PCB FR4 material) may be approximately 17 ppm/° C. The module 150 may be a SIP in some instances.

Further, the form factor of the substrate 105 may lead to further warpage issues. For example, a large footprint to accommodate the different dies and a small thickness may lead to greater warpage concerns. For example, the thickness of the substrate 105 may be as small as approximately 1.0 mm or less, or approximately 0.5 mm or less. As used herein “approximately” may refer to a range of values that are within ten percent of the stated value. For example, approximately 1 mm may refer to a range from 0.9 mm to 1.1 mm. Relatively large X-Y footprints may include substrates 105 that have lengths of approximately 25 mm or greater and widths of approximately 25 mm or greater. In one embodiment, the substrate 105 may have a footprint that is approximately 25 mm by approximately 45 mm or larger. That is, the form factor of the substrate may be such that the X-Y dimensions are an order of magnitude or two larger than the magnitude of the thickness.

In an embodiment, a plurality of dies may be provided over the substrate 105. For example, the plurality of dies may be coupled to the substrate 105 using any interconnect architecture (not show). For example, solder balls, bumps, or the like may couple the plurality of dies to the substrate 105. Additionally, while certain types of dies are shown in FIG. 1A (e.g., a compute die 120, a memory die 110, and a PMIC 125), it is to be appreciated that other types of dies, passive components, active components, and the like may be included in the SIP 150.

In an embodiment, one or more of the dies may include a compute die 120. The compute die 120 may comprise one or more of a central processing unit (CPU), a graphics processing unit (GPU), an XPU, a system on a chip (SoC), a communications die, or the like. In the illustrated embodiment, the compute die 120 is shown as a single die. Though, it is to be appreciated that multiple compute dies 120 may be included in some embodiments. Further while shown as a single die, it is to be appreciated that multiple compute dies 120 may be coupled together through an interposer, a package substrate with an embedded bridge, or other more complex multi-die modules. That is, embodiments disclosed herein should not be limited to the structure of a single isolated compute die 120.

In an embodiment, one or more of the dies on the substrate 105 may include memory dies 110. As shown, a pair of memory dies 110 is provided in FIG. 1A. Though, it is to be appreciated that one or more memory dies 110 may be included in some embodiments. In an embodiment, each of the memory dies 110 may be a high density stacked memory module. For example, a package on package (PoP) memory architecture may be used in some embodiments. The memory dies 110 may be any suitable type of memory. In a particular embodiment, the memory dies 110 are DRAMs. In addition to the memory dies 110, one or more PMICs 125 may be provided on the substrate 105. For example, three PMICs 125 are shown in FIG. 1A. In addition to the PMICs 125, power delivery components (e.g., capacitors, inductors, resistors, and the like) may be provided on the top surface of the substrate 105. Power delivery components are omitted from FIG. 1A in order to not overly complicate the Figure.

Referring now to FIG. 1B, a plan view illustration of the backside of the SIP 150 is shown, in accordance with an embodiment. In an embodiment, the backside of the SIP 150 may include a bump field 107 provided over the substrate 105. The bump field 107 may comprise a plurality of solder bumps or other interconnects. Individual interconnects are not shown in FIG. 1B in order to simplify the Figure. In an embodiment, the plurality of interconnects may include signaling interconnects, power delivery interconnects, ground interconnects and the like. The interconnects may be arranged in a regular array. In a particular embodiment, the interconnects have a tight pitch and small standoff height in order minimize the footprint of the SIP 150. For example, interconnects may be spaced at a pitch of approximately 200 μm or smaller in some embodiments. Though, larger pitches are also envisioned by some embodiments disclosed herein. The standoff height of the interconnects may also be approximately 200 μm or smaller in some embodiments.

In an embodiment, the backside of the substrate 105 may also comprise a voided region 108. The voided region 108 may be towards a center of the substrate 105. That is, the voided region 108 may be set away from the edges of the substrate 105. The voided region 108 may include an absence of interconnects. The voided region 108 may be located below the compute die 120 formed on the opposite side of the substrate 105. That is, the voided region 108 may be at least partially within an X-Y footprint of the compute die 120. In some embodiments, power delivery components or other passive components (not shown) may be provided in the voided region 108.

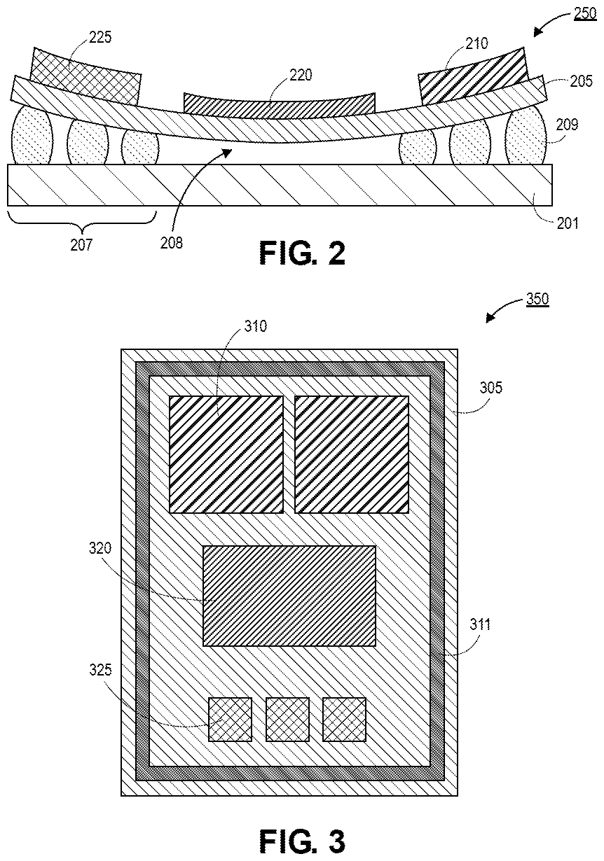

Referring now to FIG. 2, a cross-sectional illustration of a module 250 is shown, in accordance with an embodiment. The module 250 may be coupled to a board 201, such as a PCB. The module 250 may be a SIP in some embodiments. In an embodiment, interconnects 209 in the bump filed 207 may provide the coupling from the substrate 205 to the board 201. A voided region 208 may be provided at a center of the bump field 207 below the compute die 220. As illustrated the substrate 205 is significantly warped. More particularly, the warpage type is a bowl shaped warpage. In a bowl shaped warpage, the edges of the substrate 205 pull away from the board 201 further than a center of the substrate 205. In order to accommodate the warpage, the interconnects 209 may be significantly stressed. The warpage may also lead to solder bridging or non-contact opens. As the name suggests, solder bridging occurs when two neighboring interconnects 209 contact each other and cause a bridge (or short) between the two interconnects 209. A non-contact open occurs when the interconnect 209 only contacts one of two pads the interconnect 209 is designed to contact.

As shown, the module 250 may comprise a plurality of dies on the top surface of the substrate 205. The loading of dies on one side of the substrate 205 contributes to the warpage problem due to CTE mismatch, as described above. In an embodiment, the module 250 may comprise a compute die 220, such as a CPU, a GPU, an XPU, an SoC, a communications die, or the like. While shown as a single die in FIG. 2, it is to be appreciated that multiple compute dies 220 may be coupled together in some advanced processing architectures. For example, two or more compute dies 220 may be communicatively coupled together through an interposer or an embedded bridge. In the case of an interposer or an embedded bridge, the interposer or the package substrate embedding the bridge may be directly coupled to the substrate 205 instead of the compute dies 220 themselves.

In an embodiment, the plurality of dies may further comprise one or more memory dies 210. The memory dies 210 may be any type of memory die. For example, high density PoP memory devices can be used in some embodiments. The memory dies 210 may be DRAM in some instances. Additionally, the plurality of dies may also include PMICs 225. The PMICs 225 may function in coordination with power delivery components (e.g., capacitors, inductors, resistors, etc.) which may also be provided on the top surface of the substrate 205.

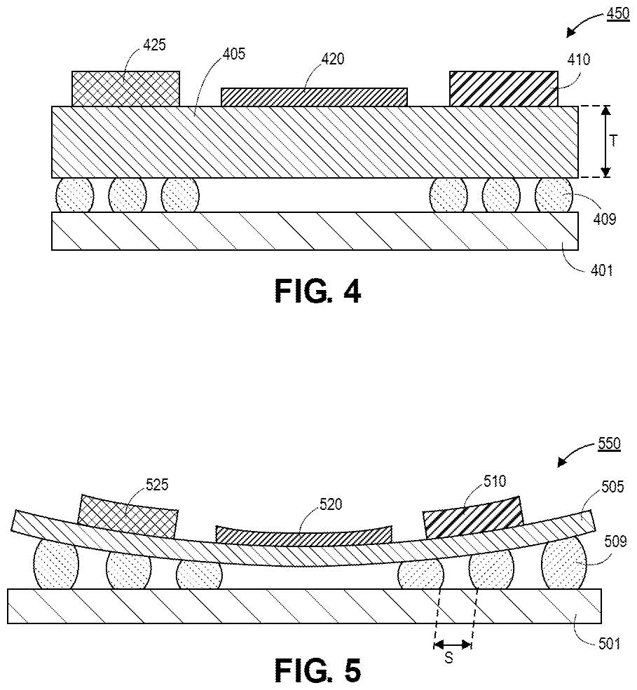

Referring now to FIG. 3, a plan view illustration of a module 350 is shown, in accordance with an embodiment. The module 350 in FIG. 3 may be substantially similar to the module 150 described above with respect to FIG. 1A, with the exception of a stiffener 311 included. That is, the module 350 may include a substrate 305. The substrate 305 may be a board, such as a PCB, or a package substrate. The substrate 305 may have a CTE that is significantly higher than the CTE of silicon. As such, warpage may be a problem with the module 350. The module 350 may be a SIP.

In an embodiment, a compute die 320 may be provided on the substrate 305. The compute die 320 may be any type of compute die 320, such as those described in greater detail above. Additionally, while a single compute die 320 is shown in FIG. 3, it is to be appreciated that multiple compute dies 320 may be used. Multiple compute dies 320 may be provided in any suitable configuration, including the use of an interposer or the like. The module 350 may further comprise one or more memory dies 310. The memory dies 310 may have any configurations, such as those described in greater detail above. One or more PMICs 325 may also be included in the module 350.

In order to mitigate warpage, a stiffener 311 may be provided. The stiffener 311 may be a rigid material with a high modulus. For example, the stiffener may include a metallic material, such as aluminum or the like. The stiffener 311 may be a ring that is provided around an outer edge of the substrate 305. A single continuous stiffener 311 is shown, but multiple stiffeners 311 may also be used in some embodiments. While the stiffener 311 may improve the warpage of the substrate 305, it is to be appreciated that the X-Y form factor of the module 350 needs to be increased in order to accommodate the placement of the stiffener 311. As such, the use of a stiffener 311 may not be suitable when small form factors are required.

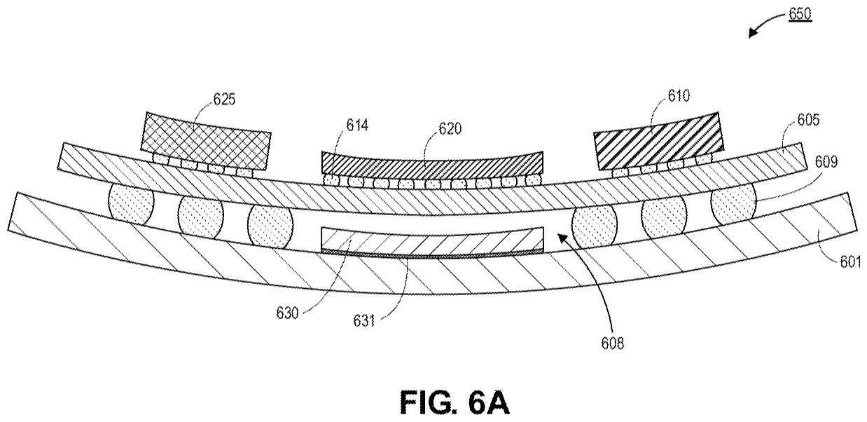

Referring now to FIG. 4, a cross-sectional illustration of a module 450 is shown, in accordance with an embodiment. The module 450 in FIG. 4 may be substantially similar to the SIP 250 in FIG. 2, with the exception of the thickness of the substrate 405. That is, the module 450 may comprise a board 401 that is coupled to the substrate 405 by interconnects 409. The interconnects 409 may be solder balls or the like. In an embodiment, the spacing and standoff height of the interconnects 409 may both be approximately 200 μm or less. In an embodiment, the module 450 may be a SIP.

Additionally, a plurality of dies may be provided on a surface of the substrate 405 opposite from the board 401. The plurality of dies may include a compute die 420. The compute die 420 may be any type of compute die 420, such as those described in greater detail above. Additionally, while a single compute die 420 is shown in FIG. 4, it is to be appreciated that multiple compute dies 420 may be used. Multiple compute dies 420 may be provided in any suitable configuration, including the use of an interposer or the like. The module 450 may further comprise one or more memory dies 410. The memory dies 410 may have any configurations, such as those described in greater detail above. One or more PMICs 425 may also be included in the module 450.

As noted above, the substrate 405 may have an increased thickness T in order to mitigate the warpage caused by the CTE mismatch between the dies and the substrate 405. In an embodiment, the substrate 405 may be increased to a thickness of approximately 0.5 mm or greater. For example, thicknesses up to approximately 2.0 mm or greater may be needed in order to account for the warpage in the module 450. Increasing the thickness of the substrate 405 results in an increase in the Z-height of the module 450. As such, the form factor is significantly impacted, and the module 450 may not be suitable for applications that demand small Z-heights (e.g., mobile devices, and the like).

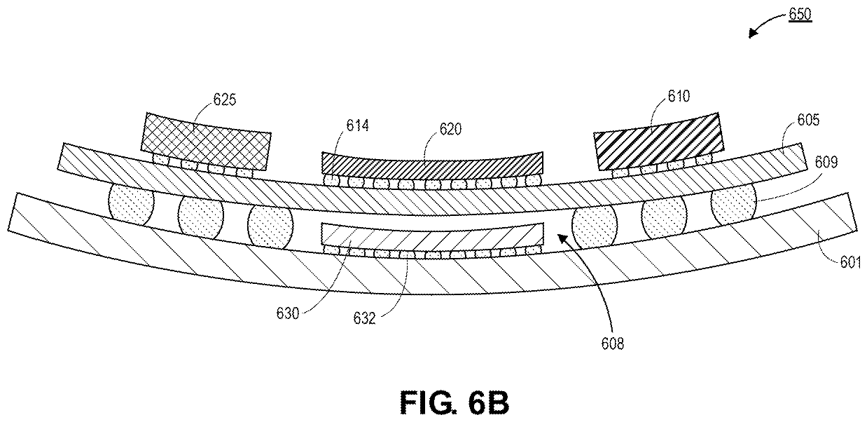

Referring now to FIG. 5, a cross-sectional illustration of a module 550 is shown, in accordance with an embodiment. In an embodiment, the module 550 may be substantially similar to the SIP 250 in FIG. 2, with the exception of the size and spacing S of the interconnects 509. That is, the module 550 may comprise a board 501 that is coupled to a substrate 505 by the interconnects 509. In an embodiment, module 550 may be a SIP.

Additionally, a plurality of dies may be provided on a surface of the substrate 505 opposite from the board 501. The plurality of dies may include a compute die 520. The compute die 520 may be any type of compute die 520, such as those described in greater detail above. Additionally, while a single compute die 520 is shown in FIG. 5, it is to be appreciated that multiple compute dies 520 may be used. Multiple compute dies 520 may be provided in any suitable configuration, including the use of an interposer or the like. The module 550 may further comprise one or more memory dies 510. The memory dies 510 may have any configurations, such as those described in greater detail above. One or more PMICs 525 may also be included in the module 550.

In an embodiment, the warpage of the substrate 505 can be accommodated by the use of larger solder interconnects 509. For example, the solder interconnects 509 may have a standoff height that is greater than approximately 200 μm. Additionally, the spacing S between the interconnects 509 may be greater than approximately 200 μm. While larger interconnects 509 with increased spacing S helps mitigate interconnect defects (e.g., solder bridging, non-contact opens, etc.), the larger interconnects also increase the form factor of the module 550. For example, the increased spacing results in the X-Y form factor of the substrate 505 being increased, and the increased standoff height increases the Z-height of the module 550. Accordingly, such a module 550 may not be suitable for small form factor applications, such as mobile devices and the like.

Accordingly, embodiments disclosed herein include architectures that mitigate the warpage without negatively impacting form factor. Particularly, embodiments utilize the voided region below the substrate to house warpage mitigating features. In one embodiment, the warpage mitigating feature is a dummy die that is coupled to the board in the voided region. The presence of the dummy die induces warpage on the board. Ideally, the warpage on the board substantially matches the warpage of the substrate. Since both are warped in a similar fashion, the effective warpage is reduced. For example, the effective warpage may be approximately 300 μm or less in some embodiments.

An alternative embodiment includes providing a dummy die on the backside of the substrate within the voided region. Placing the dummy die on the backside of the substrate compensates for the warpage induced by the dies on the front side of the substrate. As such, the effective warpage compared to the board is reduced to approximately 300 μm or less.

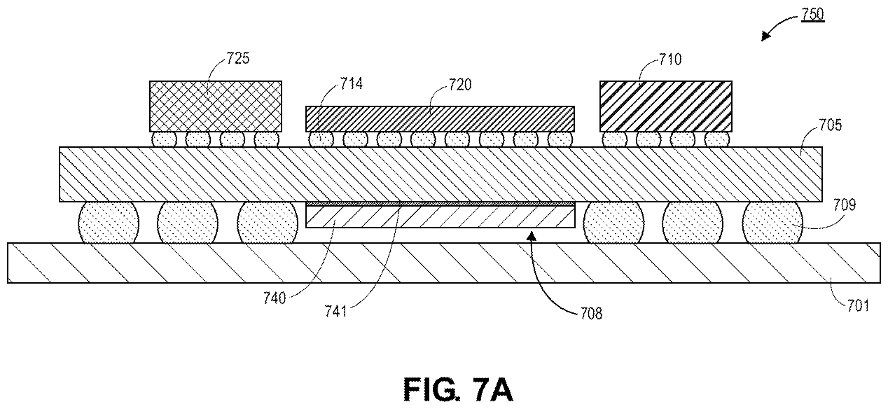

Referring now to FIG. 6A, a cross-sectional illustration of a module 650 is shown, in accordance with an embodiment. In an embodiment, the module 650 comprises a board 601, such as a PCB. In an embodiment, a substrate 605 is coupled to the board 601 by interconnects 609. The interconnects 609 may be provided around a perimeter of the substrate 605 in a bump field so that a voided region 608 is provided at the center of the substrate 605. In an embodiment, the interconnects 609 may have a spacing and standoff height that are both approximately 200 μm or less. In an embodiment, module 650 may be a SIP.

In an embodiment, the substrate 605 may comprise a board or a package substrate. That is, the substrate 605 may comprise organic layers with (or without) fiber reinforcement. In some instances the substrate 605 may comprise a core. In an embodiment, the substrate 605 has a thickness that is approximately 0.5 mm or less.

In an embodiment, a plurality of dies may be provided on a surface of the substrate 605 opposite from the board 601. The plurality of dies may include a compute die 620. The compute die 620 may be any type of compute die 620, such as those described in greater detail above. Additionally, while a single compute die 620 is shown in FIG. 6A, it is to be appreciated that multiple compute dies 620 may be used. Multiple compute dies 620 may be provided in any suitable configuration, including the use of an interposer or the like. The module 650 may further comprise one or more memory dies 610. The memory dies 610 may have any configurations, such as those described in greater detail above. One or more PMICs 625 may also be included in the module 650. As shown, the plurality of dies on the substrate 605 may lead to warpage in the substrate 605 due to unbalanced CTEs. In the particular embodiment shown in FIG. 6A, the warpage may be a bowl shaped warpage. In an embodiment, the plurality of dies may be coupled to the substrate 605 by interconnects 614, such as solder balls, bumps, or the like.

In order to mitigate the warpage, a die 630 may be mounted to the board 601. The die 630 may be at least partially below a footprint of the compute die 620. In some embodiments, the die 630 may have a form factor that is substantially similar to that of the compute die 620. Though, the die 630 may also have a different form factor than the compute die 620 in other embodiments. The die 630 may be mounted to the board 601 by an adhesive 631, such as a die attach film (DAF). The die 630 may comprise silicon or another low CTE material. In some embodiments, the die 630 may be a dummy die. That is, there may not be electrical features integrated within the die 630 that are coupled to circuitry within the module 650. For example, while there may be conductive pads (not shown) electrically coupling die 630 to board 601 through interconnect features such as solder balls (not shown), die 630 does not include circuitry such as transistors capable of implementing logic functions. Due to the low CTE of the die 630, the board 601 may also experience warpage. Ideally, the warpage in the board 601 matches the warpage in the substrate 605. For example, an effective warpage (i.e., the difference between the warpage of the substrate 605 and the board 601) may be approximately 300 μm or less.

Referring now to FIG. 6B, a cross-sectional illustration of a module 650 is shown, in accordance with an additional embodiment. In an embodiment, the module 650 in FIG. 6B may be substantially similar to the module 650 in FIG. 6A, with the exception of the attachment of the die 630 to the board 601. Instead of being coupled to the board 601 by an adhesive, the die 630 in FIG. 6B is coupled to the board by interconnects 632. The use of interconnects allows for the die 630 to be electrically coupled to the board 601. As such, active circuitry, power delivery functionality, passives, or the like may be included in the die 630.

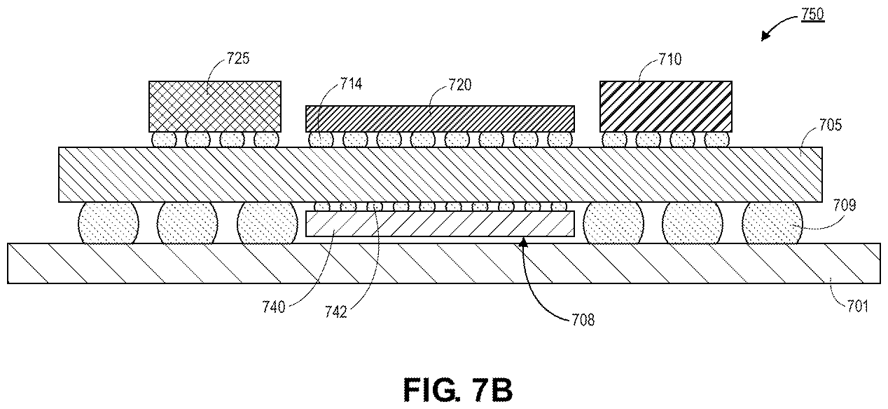

Referring now to FIG. 7A, a cross-sectional illustration of a module 750 is shown, in accordance with an additional embodiment. In an embodiment, the module 750 comprises a board 701, such as a PCB. In an embodiment, a substrate 705 is coupled to the board 701 by interconnects 709. The interconnects 709 may be provided around a perimeter of the substrate 705 in a bump field so that a voided region 708 is provided at the center of the substrate 705. In an embodiment, the interconnects 709 may have a spacing and standoff height that are both approximately 200 μm or less. In an embodiment, the module 750 may be a SIP.

In an embodiment, the substrate 705 may comprise a board or a package substrate. That is, the substrate 705 may comprise organic layers with (or without) fiber reinforcement. In some instances the substrate 705 may comprise a core. In an embodiment, the substrate 705 has a thickness that is approximately 0.5 mm or less.

In an embodiment, a plurality of dies may be provided on a surface of the substrate 705 opposite from the board 701. The plurality of dies may include a compute die 720. The compute die 720 may be any type of compute die 720, such as those described in greater detail above. Additionally, while a single compute die 720 is shown in FIG. 7A, it is to be appreciated that multiple compute dies 720 may be used. Multiple compute dies 720 may be provided in any suitable configuration, including the use of an interposer or the like. The module 750 may further comprise one or more memory dies 710. The memory dies 710 may have any configurations, such as those described in greater detail above. One or more PMICs 725 may also be included in the module 750. In an embodiment, the plurality of dies may be coupled to the substrate 705 by interconnects 714, such as solder balls, bumps, or the like.

In order to mitigate the warpage, a die 740 may be mounted to the backside of the substrate 705. The die 740 may be at least partially below a footprint of the compute die 720. In some embodiments, the die 740 may have a form factor that is substantially similar to that of the compute die 720. Though, the die 740 may also have a different form factor than the compute die 720. In other embodiments, the die 740 may be mounted to the substrate 705 by an adhesive 741, such as a DAF. The die 740 may comprise silicon or another low CTE material. In some embodiments, the die 740 may be a dummy die. That is, there may not be any electrical features integrated within the die 740 that are coupled to circuitry within the module 750. Due to the low CTE of the die 740, the forces due to CTE mismatch are balance between the top and bottom surface of the substrate 705. As such, the overall effect is to mitigate warpage in the substrate 705. For example, an effective warpage (i.e., the difference between the warpage of the substrate 705 and the board 701) may be approximately 300 μm or less.

Referring now to FIG. 7B, a cross-sectional illustration of a module 750 is shown, in accordance with an additional embodiment. In an embodiment, the module 750 in FIG. 7B may be substantially similar to the module 750 in FIG. 7A, with the exception of the attachment of the die 740 to the substrate 705. Instead of being coupled to the substrate 705 by an adhesive, the die 740 in FIG. 7B is coupled to the board by interconnects 742. The use of interconnects allows for the die 740 to be electrically coupled to the substrate 705. As such, active circuitry, power delivery functionality, passives, or the like may be included in the die 740

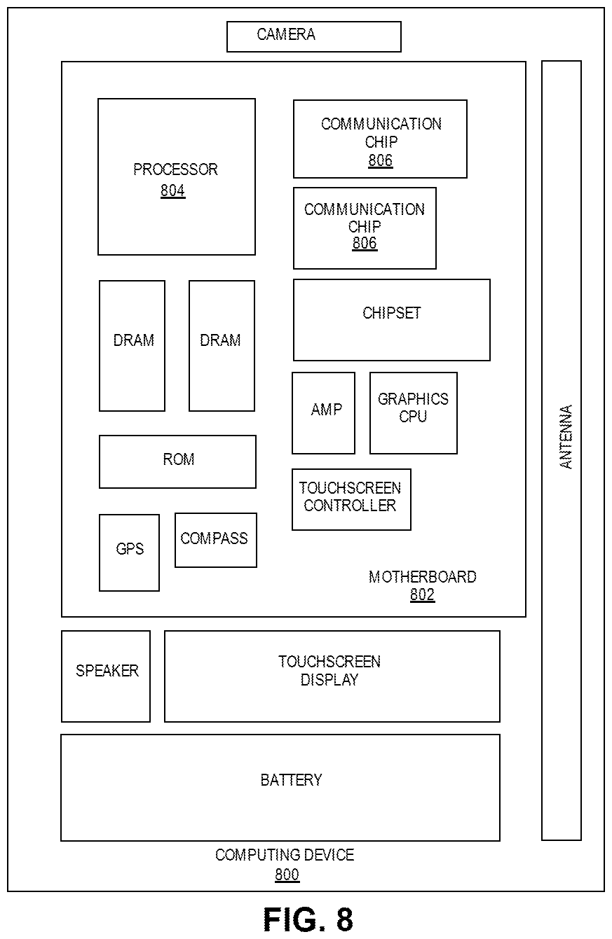

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of a SIP that includes a die in the voided region of the bump field between the substrate and the board, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of a SIP that includes a die in the voided region of the bump field between the substrate and the board, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a substrate with a first surface and a second surface opposite from the first surface; a plurality of first dies coupled to the first surface of the substrate; and a bump field on the second surface of the substrate, wherein the bump field comprises a voided region towards a center of the substrate; and a second die coupled to the second surface of the substrate, wherein the second die is provided in the voided region.

Example 2: the electronic package of Example 1, wherein the second die does not include transistors.

Example 3: the electronic package of Example 1 or Example 2, wherein at least one of the plurality of first dies is provided directly over the second die.

Example 4: the electronic package of Example 3, wherein the at least one of the plurality of first dies over the second die has the same dimensions as the second die.

Example 5: the electronic package of Examples 1-4, wherein the second die is coupled to the substrate by an adhesive.

Example 6: the electronic package of Examples 1-5, wherein the second die is coupled to the substrate by interconnects.

Example 7: the electronic package of Example 6, wherein the second die is configured to supply power delivery and/or memory functionality to the electronic package.

Example 8: the electronic package of Examples 1-7, wherein the substrate is a package substrate.

Example 9: the electronic package of Examples 1-7, wherein the substrate is a board.

Example 10: the electronic package of Examples 1-9, wherein an effective warpage of the substrate at room temperature is less than approximately 300 μm.

Example 11: an electronic system, comprising: a first substrate; a second substrate coupled to the first substrate by a plurality of interconnects between the first substrate and the second substrate, wherein a voided region without interconnects is provided at a location towards a center of the second substrate; a plurality of first dies coupled to the second substrate on a surface opposite from the first substrate; and a second die coupled to the first substrate, wherein the second die is positioned within the voided region.

Example 12: the electronic system of Example 11, wherein an effective warpage between the first substrate and the second substrate is approximately 200 μm or less.

Example 13: the electronic system of Example 11 or Example 12, wherein the second die is coupled to the first substrate by an adhesive.

Example 14: the electronic system of Examples 11-13, wherein the second die is coupled to the first substrate by interconnects.

Example 15: the electronic system of Examples 11-14, wherein at least one of the plurality of first dies is provided directly over the second die.

Example 16: the electronic system of Examples 11-15, wherein the first substrate is a first board, and wherein the second substrate is a second board or a package substrate.

Example 17: the electronic system of Examples 11-16, wherein the plurality of first dies comprises at least a compute die, a power management integrated circuit (PMIC), and a memory die.

Example 18: an electronic system, comprising: a first substrate; a second substrate coupled to the first substrate; a first die coupled to the second substrate on a surface opposite from the first substrate; and a second die provided in a gap between the first substrate and the second substrate, wherein the second die is provided under the first die.

Example 19: the electronic system of Example 18, wherein the second die is coupled to the first substrate, or wherein the second die is coupled to the second substrate.

Example 20: the electronic system of Example 18 or Example 19, wherein the electronic system is part of a personal computer, a server, a mobile device, a tablet, or an automobile.

What is claimed is:

1. An electronic package, comprising:
a substrate with a first surface and a second surface opposite from the first surface;
a plurality of first dies coupled to the first surface of the substrate; and
a bump field on the second surface of the substrate, wherein the bump field comprises a voided region towards a center of the substrate; and
a second die coupled to the second surface of the substrate, wherein the second die is provided in the voided region.

2. The electronic package of claim 1, wherein the second die does not include transistors.

3. The electronic package of claim 1, wherein at least one of the plurality of first dies is provided directly over the second die.

4. The electronic package of claim 3, wherein the at least one of the plurality of first dies over the second die has the same dimensions as the second die.

5. The electronic package of claim 1, wherein the second die is coupled to the substrate by an adhesive.

6. The electronic package of claim 1, wherein the second die is coupled to the substrate by interconnects.

7. The electronic package of claim 6, wherein the second die is configured to supply power delivery and/or memory functionality to the electronic package.

8. The electronic package of claim 1, wherein the substrate is a package substrate.

9. The electronic package of claim 1, wherein the substrate is a board.

10. The electronic package of claim 1, wherein an effective warpage of the substrate at room temperature is less than approximately 300 μm.

11. An electronic system, comprising:
a first substrate;
a second substrate coupled to the first substrate by a plurality of interconnects between the first substrate and the second substrate, wherein a voided region without interconnects is provided at a location towards a center of the second substrate;
a plurality of first dies coupled to the second substrate on a surface opposite from the first substrate; and
a second die coupled to the first substrate, wherein the second die is positioned within the voided region.

12. The electronic system of claim 11, wherein an effective warpage between the first substrate and the second substrate is approximately 200 μm or less.

13. The electronic system of claim 11, wherein the second die is coupled to the first substrate by an adhesive.

14. The electronic system of claim 11, wherein the second die is coupled to the first substrate by interconnects.

15. The electronic system of claim 11, wherein at least one of the plurality of first dies is provided directly over the second die.

16. The electronic system of claim 11, wherein the first substrate is a first board, and wherein the second substrate is a second board or a package substrate.

17. The electronic system of claim 11, wherein the plurality of first dies comprises at least a compute die, a power management integrated circuit (PMIC), and a memory die.

18. An electronic system, comprising:
a first substrate;
a second substrate coupled to the first substrate;
a first die coupled to the second substrate on a surface opposite from the first substrate; and
a second die provided in a gap between the first substrate and the second substrate, wherein the second die is provided under the first die.

19. The electronic system of claim 18, wherein the second die is coupled to the first substrate, or wherein the second die is coupled to the second substrate.

20. The electronic system of claim 19, wherein the electronic system is part of a personal computer, a server, a mobile device, a tablet, or an automobile.
